(19) United States
(12) Patent Application Publication
(10) Pub. No.: US 2026/0143871 A1
(43) Pub. Date: May 21, 2026

(54) LED TUNNEL JUNCTION ARCHITECTURE WITH HIGH LIGHT OUTPUT RANGE

(71) Applicant: LUMILEDS LLC, San Jose, CA (US)

(72) Inventors: Robert ARMITAGE, Cupertino, CA (US); Jeff DiMaria, Scotts Valley, CA (US); Yu-Chen Shen, Sunnyvale, CA (US)

(73) Assignee: LUMILEDS LLC, San Jose, CA (US)

(21) Appl. No.: 18/953,804

(22) Filed: Nov. 20, 2024

(51) Int. Cl. H01L 33/46; H01L 27/15; H01L 33/38

(52) U.S. Cl. CPC H10H 20/841; H10H 20/8312; H10H 29/10

(57) ABSTRACT

An LED or microLED light source with multiple light-emitting diode stacks separated by tunnel junction(s). The diode stacks of the light source are independently addressable leading to a light source with high light output range.

### FIELD OF THE INVENTION

The invention relates generally to LED light sources.

### BACKGROUND

Semiconductor light emitting diodes (“LEDs”) are among the most efficient light sources currently available. The emission spectrum of an LED typically exhibits a single narrow peak at a wavelength determined by the structure of the device and by the composition of the semiconductor materials from which it was constructed.

Light output (luminance or candela per area) of a LED device is an important metric for certain applications. One method of achieving high light output is to use a tunnel junction to stack LEDs. Stacked LEDs provide multiple active regions and thereby increases the candela per area (Cd/A) and the total luminance of the LED device. Most LED devices with tunnel junctions and stacked LEDs apply a high voltage to the device to activate all the active regions of the device.

### SUMMARY

This application discloses an LED light source architecture for a stacked LED device that allows for the active regions of the device to be independently addressable. This architecture allows one or more active regions in the device to be activated or deactivated, which gives the LED light source a high light output range.

In one embodiment, the LED light source has two light-emitting diode stacks, each stack having an N-doped semiconductor layer, a P-doped semiconductor layer, and an active region between the N- and P-doped layers configured to emit light. The two diode stacks (the first diode stack and the second diode stack) are separated from each other by a tunnel junction. This LED light source has three terminals. The first terminal, made from a first metal, contacts the N-doped layer of the first diode stack. The first terminal coats a portion of the sidewalls of the first and second diode stacks. A dielectric layer also coats the sidewalls of the two diode stacks. The combination of the dielectric layer and the metal terminal forms a reflective coating on the sidewalls of two diode stacks. In some embodiments, the dielectric layer comprises a distributed Bragg reflector (DBR). The second terminal, made from a second metal, contacts the N-doped layer of the second diode stack. The third terminal, made from a third metal, contacts the P-doped layer of the second diode stack. In some embodiments, the LED light source has a transparent conducting oxide (TCO) layer in contact with the P-doped layer of the second diode stack. The third terminal is electrically connected to the TCO layer through a metal-coated via in the dielectric layer.

The light-emitting diode stacks of above-described LED light source are independently addressable, i.e. one diode stack may be activated to emit light while the other diode stack is deactivated. For example, by grounding the first and second terminals and driving the third terminal at a voltage sufficient to activate the second diode stack, only the second diode stack is activated to emit light. In another example, by grounding the first and third terminals and driving the second terminal at voltage sufficient to activate the first diode stack, only the first diode stack is activated to emit light. In another example, by grounding the first terminal, driving the second terminal at a voltage sufficient to activate the first diode stack, and driving the third terminal at voltage sufficient to activate both diode stacks, both the first and the second diode stacks are activated to emit light.

In addition to driving the terminals at different voltages, the average current supplied to those terminals at the stated voltages may be modulated by pulse width modulation (PWM). Changing the average current supplied will modulate the brightness of light emission from the diode stack whose current is being modulated. One of ordinary skill in the art would understand that the ability to activate or deactivate any particular diode stack coupled with the ability of modulate the brightness of diode stacks that are activated leads to an LED light source with a high light output range.

In some embodiments, the second terminal is situated towards the center of the LED light source. In such a situation, portions of the semiconductor layers of the second diode stack separate the first terminal from the second terminal. In some embodiments, the second terminal is situated adjacent to the first terminal with no portions of the semiconductor layers of the second diode stack separating the first terminal from the second terminal. In some embodiment where the second terminal is situated adjacent to the first terminal, only a dielectric layer separates the first terminal from the second terminal.

In some embodiments, the LED light source has metal layer coating the first, the second, and the third terminals. In some embodiments, the metal layer only coats the first and the third terminals. The combination of the metal layer and the metal of the terminal forms a metal stack. This metal stack along with the dielectric layer surrounding the LED light source forms a reflective coating around the LED light source. The use of a metal stack instead of a single metal layer allows the reflective coating to be configured to better reflect the specific wavelengths of light being emitted by the active regions of the diode stacks. For example, specific metals or metal alloys may be chosen for the terminal metal and the metal of the metal layer that are optimized for reflecting specific wavelengths of light.

In some embodiments, the LED light source is a microLED light source. In some embodiments, the principle light emission surface of the LED light source is a surface of the N-doped semiconductor layer of the first diode stack. In some embodiments, the principle light emission surface is roughened.

In some embodiments, the LED light source has three light-emitting diode stacks and four terminals. The LED light source has two tunnel junctions. One tunnel junction separating the first diode stack from the second diode stack. A second tunnel junction separating the second diode stack from the third diode stack. The first terminal is electrically connected to the N-doped layer of the first diode stack. The second terminal is electrically connected to the N-doped layer of the second diode stack. The third terminal is electrically connected to the P-doped layer of the third diode stack. The fourth terminal is electrically connected to the N-doped layer of the third diode stack. The active regions of the diode stacks are independently addressable. Having three independently addressable light-emitting diode stacks gives the LED light source an even greater light output range. One of ordinary skill in the art would understand that greater than 3 diode stacks may be used in an LED light source and each diode stack can be made independently addressable based on the teachings in this application.

In some embodiments, the active regions of the LED light source emit different wavelengths of light. Since the active regions of the LED light source are independently addressable, one can control the amount of light emitted from each active region and therefore control the overall color of light emitted by the LED light source. For example, the active region of the first diode stack may emit light of wavelength λ1 and the active region of the second diode stack may emit light of wavelength λ2. If only the first diode stack is activated, then the LED light source will emit light with wavelength λ1. If only the second diode stack is activated, then the LED light source will emit light with wavelength λ2. If both diode stacks of the light source are activated, then the light source will emit light with a color that results in the combination of λ1 wavelength and λ2 wavelength light. In this way, the LED light source may be used as a color-tunable light source. LED light sources with 2 or more diode stacks may have active regions that emit different wavelengths of light.

In one embodiment, the LED light source has two light-emitting diode stacks, each stack having an N-doped semiconductor layer, a P-doped semiconductor layer, and an active region between the N- and P-doped layers configured to emit light. The two diode stacks (the first diode stack and the second diode stack) are separated from each other by a tunnel junction. The N-doped semiconductor layer of the second diode stack has a lateral electrical resistance greater than the lateral electrical resistance of the N-doped semiconductor layer of the first diode stack. This LED light source has two terminals. The first terminal electrically contacts the N-doped layer of the first diode stack and the N-doped layer of the second diode stack. The second terminal electrically contacts the P-doped layer of the second diode stack.

In this embodiment, the active region of the first diode stack may be activated or deactivated depending on the voltages applied to the first and second terminals. For example, applying greater than 5.5 volts to the second terminal and grounding the first terminal will activate both active regions of the LED light source to emit light, where the light output power increases super-linearly with respect to applied voltage as the voltage exceeds 5.5 volts. Whereas, applying greater than or equal to 3 volts but less than 6 volts to the second terminal and grounding the first terminal will deactivate the first diode stack leaving the second diode stack activated. The ability to completely deactivate one diode stack gives this LED light source a high light output range since light output may be lowered beyond the point possible if both active regions must remain activated.

In some embodiments, the principal light emission surface of the LED light source is a surface of the N-doped semiconductor layer of the first diode stack. In alternative embodiments, the second terminal comprises a transparent conducting oxide (TCO) and also serves as the principal light emission surface of the LED light source.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 schematically illustrates a cross-sectional view of an example three-terminal LED light source.

FIG. 2 schematically illustrates a cross-sectional view of an example two-terminal LED light source.

FIG. 3 illustrates a circuit diagram of the LED light source of FIG. 2.

### DETAILED DESCRIPTION

The following detailed description should be read with reference to the drawings, in which identical reference numbers refer to like elements throughout the different figures. The drawings are not to scale, depict selective embodiments, and are not intended to limit the scope of the invention. The detailed description illustrates by way of example, not by way of limitation, the principles of the invention.

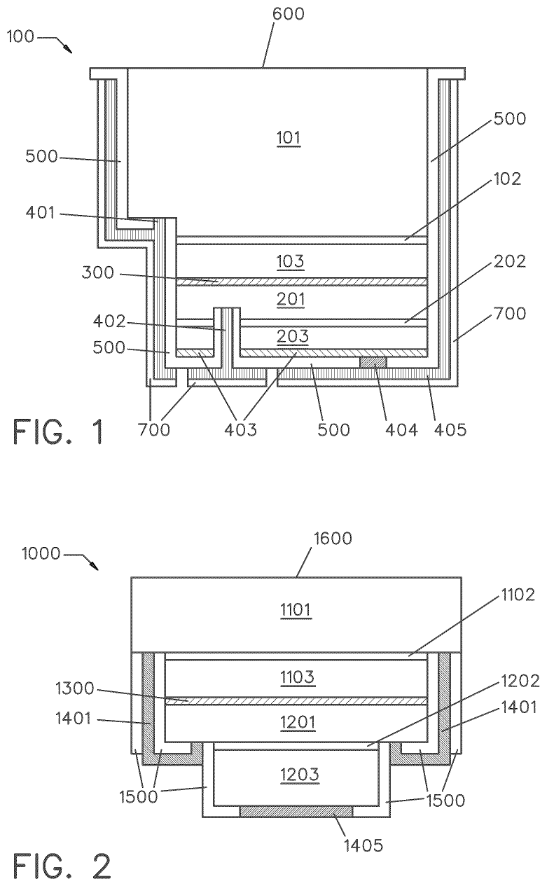

FIG. 1 shows a schematic cross-sectional view of an example LED light source 100. Light source 100 may be either an LED or a microLED light source. Light source 100 has two diode stacks. The first diode stack includes N-doped semiconductor layer 101, active region 102, and P-doped semiconductor layer 103. The second diode stack includes N-doped semiconductor layer 201, active region 202, and P-doped semiconductor layer 203. The semiconductor layers may comprise a Group III-Nitride material. Other suitable semiconductor materials include, for example, Group III-Phosphide materials, Group III-Arsenide materials, and Group II-VI materials. The two diode stacks are separated by tunnel junction 300. The tunnel junction allows current flow, e.g. two-way tunneling of electrons and holes, through a very thin depletion region. This is achieved by suitable heavy doping to create the tunnel junction. In some embodiments, the two diode stacks of light source 100 may emit the same wavelength of light. In other embodiments, the first stack which includes active region 102 emits a different wavelength of light than the second stack which includes active region 202.

Light source 100 has three terminals. Terminal 401 which contacts N-doped semiconductor layer 101 of the first diode structure is a first terminal. Terminal 402 which contacts N-doped semiconductor layer 201 is a second terminal. Terminal 405, which is electrically connected to bottom contact 403 through metal-coated via 404, is a third terminal. Bottom contact 403 contacts P-doped semiconductor layer 203.

Terminal 401 may comprise a conductive metal, for example, silver, aluminum, or gold. Terminal 401 also coats one sidewall of light source 100 and a portion of the bottom of light source 100. For example, FIG. 1 shows terminal 401 coating the left sidewall of semiconductor layers 101, 103, 201, and 203. Terminal 401 is separated from these semiconductor layers by dielectric layer 500 except for where terminal 401 makes contact with N-doped semiconductor layer 101. Dielectric layer 500 may be composed of a transparent dielectric material with low refractive index such as, for example, silicon dioxide (SiO₂). Other suitable materials for dielectric layer include magnesium fluoride (MgF₂), or silicon nitride. In some embodiments, dielectric layer 500 may include a distributed Bragg reflector (DBR), which consists of an alternating sequence of layers of two different optical materials with different refractive indices. The interface between dielectric layer 500 and terminal 401 has a critical angle that allows for total internal reflection at that interface. Therefore, terminal 401 along with dielectric layer 500 forms a reflective side coating for the LED light source that reflects radiation emitted from the side of LED light source, increasing the light emitted from top surface 600 of the LED light source. For microLEDs, reflection of light by terminal 401 is particularly important for increasing the light emission since proportionally more light is emitted from the sides of a microLED compared to a non-microLED. Advantageously, terminal 401 serves both as an electrical terminal for the LED light source and as a reflective side coating.

Terminal 402 may comprise a conductive metal, for example, silver or aluminum. Terminal 402 is separated from terminal 401 by a gap at the bottom of the LED light source. Terminal 402 is also electrically insulated from semiconductor layer 203, active region 202, and bottom contact 403 by dielectric layer 500. The combination of terminal 402 and dielectric layer 500 forms a reflective coating which will reflect light emitted from the bottom of the LED light source. In another embodiment terminal 402 may be advantageously placed adjacent to terminal 401 separated from terminal 401 by dielectric layer 500. In this configuration, terminal 402 does not interrupt active region 202, which allows active region 202 to have a greater surface area and produce more light. In this configuration, terminal 402, in combination with dielectric layer 500, would reflect a portion of the light emitted from the side of the LED as well as from the bottom of the LED.

Bottom contact 403 may comprise a transparent conducting oxide, such as for example Indium tin oxide (ITO). Bottom contact 403 may comprise a layer of material in contact with semiconductor layer 203 at the bottom of the LED die as shown in FIG. 1. Bottom contact 403 is electrically connected to terminal 405 by via 404. If terminal 405 comprises aluminum then via 404 may comprise for example a Ti/Pt alloy coated via. Other alloys or metals may be used for example Ti, Pt, Ag, Au, Al, Ni, Pd, or various combinations of these metals.

Light source 100 may optionally have a metal layer 700 coating the sidewalls and the bottom of light source 100 and, in particular, coating terminals 401, 402, and 405, would make metal layer 700 a part of the terminals. Metal layer 700 combined with the terminals form a metal stack. Metal layer 700 may be used to make the terminals compatible with downstream pixel attach processes which may involve either laser-induced forward transfer (LIFT) followed by solder reflow or stamp-transfer Au-Au bonding. Metal layer 700 itself may be a metal stack comprising Ti/Ni/Au, Ti/Ni/Cu/Au, Ti/Ni/AuSn or some variation of that stack. One or more layers of Ni, Ti, Ti/Ni may be the first (inner) layers of the stack, and Au or AuSn may be the last (outer) layers of the stack to prevent oxidation. Metal layer 700 may also consist of Au only to make the terminal compatible with a stamp transfer Au-Au bonding process. Metal layer 700 may be used to better reflect certain wavelengths of light emitted by the LED. For example, terminal 401 and metal layer 700 forms a metal stack configured to reflect light emitted from the left side of light source 100 illustrated in FIG. 1. Terminal 405 and metal layer 700 forms a metal stack configured to reflect light emitted from the right side of light source 100 illustrated in FIG. 1. The metal content of metal layer 700 can be optimized for the wavelength(s) of light emitted by light source 100.

The two active regions (102, 202) of light source 100 are independently addressable by applying varying voltages to the three terminals (401, 402, 405) of the light source. Applying 0 volts to terminals 401 and 402 and 3 volts to terminal 405 will only activate active region 202 to emit light. Applying 0 volts to terminals 401 and 405 and 3 volts to terminal 402 will only activate active region 102 to emit light. Applying 0 volts to terminal 401, 3 volts to terminal 402, and 6 volts to terminal 405 will activate both active region 102 and active region 202 to emit light.

The ability to completely deactivate one active region of the light source is advantageous for achieving a high light output range by extending the low end of the light output range. Generally, light output from a diode stack can be controlled by varying the current flow through the stack by, for example, pulse width modulation (PWM) of the current. But, when using PWM, there is a minimum pulse width, which corresponds to a lower limit in the light output of the light source. By deactivating one active region, the lower limit of light output of the light source is essentially halved, yet the light source retains the ability to reach its maximum light output by driving both diode stacks on maximum current. This gives the light source a greater light output range compared to a light source that cannot deactivate one diode stack.

Further, the light emission of each diode stack may be independently controlled by, for example, driving each diode stack at a different PWM. Independent control of each diode stack allows for finer control of the light output and a greater degree of freedom since with two independently controlled diode stacks, one may be able to achieve a particular level of light output in multiple ways. In embodiments where the active regions of the light source emit different colors of light or different wavelengths of light, the color of light output of the light source as whole is a mixture of the light emitted from each active region. By controlling the amount of light emitted from each active region, the color of light output of the light source may be varied and controlled.

In some embodiments, light source 100 may have three or more diode stacks. Each added diode stack requires an additional terminal. For example, a three-diode-stack light source would have 4 terminals. One terminal electrically connected to the P-doped layer of the bottom diode stack. A second terminal electrically connected to the N-doped layer of the bottom diode stack. A third terminal electrically connected to the N-doped layer of the middle diode stack. A fourth terminal electrically connected to the N-doped layer of the top diode stack. The diode stacks are independently addressable. To activate all three stacks would require approximately 9 volts across all stacks, for the case of blue-emitting diodes. A combination of 0 volts, 3 volts, 6 volts, and 9 volts applied across the terminals may be used to independently activate or deactivate individual stacks. For example, applying 0, 0, 3 and 3 volts across the terminals will activate only the middle diode stack. Other combinations of voltages to activate or deactivate other combinations of diode stacks will be understood by those skilled in the art. The operating voltage of a single light-emitting diode depends on the emission wavelength and other design details and may vary between 1.8 and 4.0 volts for visible light-emitting diodes.

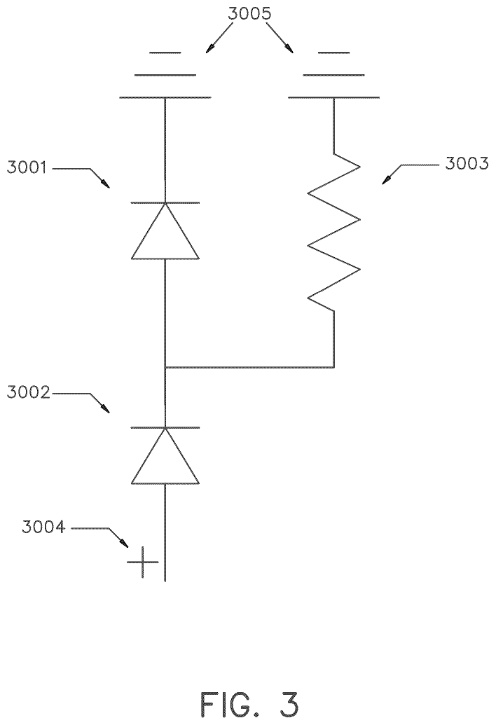

FIG. 2 illustrates a cross-sectional view of light source 1000 which has two diode stacks and two terminals. Light source 1000 may be either an LED or a microLED light source. The first diode stack comprises N-doped semiconductor layer 1101, active region 1102, and P-doped semiconductor layer 1103. The second diode stack comprises N-doped semiconductor layer 1201, active region 1202, and P-doped semiconductor layer 1203. These two diode stacks are separated by tunnel junction 1300. The semiconductor layers may comprise a Group III-Nitride material. Other suitable semiconductor materials include, for example, Group III-Phosphide materials, Group III-Arsenide materials, and Group II-VI materials. In some embodiments, the two diode stacks of light source 1000 may emit the same wavelength of light. In other embodiments, the first stack which includes active region 1102 emits a different wavelength of light than the second stack which includes active region 1202.

Light source 1000 has two terminals. Anode terminal 1405 contacts P-doped semiconductor layer 1203. Cathode terminal 1401 contacts both N-doped semiconductor layer 1101 and N-doped semiconductor layer 1201. Although cathode terminal 1401 is illustrated in FIG. 2 as two separate pieces, light source 1000 only has one cathode terminal. The cathode terminal 1401 pieces illustrated in FIG. 2 are connected in and out of the plane of FIG. 2, i.e. cathode terminal 1401 wraps around light source 1000.

In light source 1000, the two diode stacks are connected in series and a resistor representing the lateral resistance of N-doped semiconductor layer 1201 is connected in parallel with the top diode stack. The electrical connections of light source 1000 may be better illustrated with reference to FIG. 3. Diode 3002 in FIG. 3 corresponds to the bottom diode stack (1201, 1202, and 1203) in FIG. 2. Diode 3001 corresponds to the top diode stack (1101, 1102, and 1103). Terminal 3004 corresponds to anode terminal 1405. Ground 3005 in FIG. 3 corresponds to cathode terminal 1401. Resistor 3003 in FIG. 3 corresponds to the lateral resistance of N-doped semiconductor layer 1201. The lateral resistance of N-doped semiconductor layer 1201 is configured to be greater than the lateral resistance of N-doped semiconductor layer 1101.

In reference to FIG. 3, a voltage greater than or equal to 5.5 volts applied to terminal 3004 (terminal 1405) will induce a ≥2.5 volt drop across diode 3002, a ≥2.5 volt drop across diode 3001 and resistor 3003. In this situation, current will flow through both diode 3001 and 3002, activating them both to emit light. On the other hand, a voltage greater than or equal to 2.5 volts but less than 5.5 volts applied to terminal 3004 (terminal 1405) will induce a greater than or equal to 2.5 volt drop across diode 3002 and resistor 3003 and a less than 2.5 volt drop across diode 3001. The >2.5 volt drop across diode 3002 allows current to flow through diode 3002, which activates diode 3002 to emit light. But the <2.5 volt drop across diode 3001 does not allow for current flow, which does not activate diode 3001. In this situation, current will flow through the alternate path provided, i.e. through resistor 3003. In this manner, active region 1102 can either be activated or deactivated depending on the voltage applied to anode terminal 1405. The voltages stated above refer to the case of light source 1000 incorporating two blue-emitting diodes. Light source 1000 could instead comprise LEDs having different emission wavelengths with different operating voltages.

The light output power of the LED light source may also be controlled by applied voltage. For example, the light output power may increase in a super-linear fashion with respect to the voltage applied to the anode terminal as the applied voltage exceeds 5.5 volts.

The ability to completely deactivate active region 1102 in light source 1000 is advantageous for achieving a high light output range by extending the low end of the light output range. As discussed above, when using PWM, there is a minimum pulse width, which corresponds to a lower limit in the light output of the light source. By deactivating active region 1102, the lower limit of light output of the light source is essentially halved, yet the light source retains the ability to reach its maximum light output by driving both diode stacks on maximum current. This gives the light source a greater light output range compared to a light source that cannot deactivate one diode stack.

In some embodiments, surface 1600 of the light source is the primary light emitting surface. Surface 1600 may be roughened to increase light emission by decreasing internal reflection at the surface. In some embodiment, anode terminal 1405 may be made from a transparent conductive oxide such as ITO. In this embodiment, light may be emitted through anode terminal 1405 and a metal layer and a DBR may be coated on surface 1600 to reflect light toward anode terminal 1405.

Dielectric layer 1500 may be coated on various components of light source 1000 to prevent electrical shorts. For example, dielectric layer 1500 separates terminal 1401 from semiconductor layers 1103, 1201, and 1203.

This disclosure is illustrative and not limiting. Further modifications will be apparent to one skilled in the art in light of this disclosure and are intended to fall within the scope of this appended claims.

What is claimed is:

1. A LED light source comprising:
a first diode stack comprising: an N-doped semiconductor layer, a P-doped semiconductor layer, and an active region between the N and P doped layers configured to emit light;
a second diode stack comprising: an N-doped semiconductor layer, a P-doped semiconductor layer, and an active region between the N and P doped layers configured to emit light;
a tunnel junction separating the first and second diode stacks;
a dielectric layer coating sidewalls of the first and the second diode stacks;
a first terminal comprising a first metal, the first terminal in contact with the N doped layer of the first diode stack, the first terminal in contact with the dielectric layer and coating a portion of the sidewalls of the first diode stack and a portion of the sidewalls of the second diode stack;
a second terminal comprising a second metal, the second terminal in contact with the N doped layer of the second diode stack; and
a third terminal comprising a third metal, the third terminal in contact with the P doped layer of the second diode stack, the third terminal in contact with the dielectric layer and coating a portion of the sidewalls of the first diode stack and a portion of the sidewalls of the second diode stack,
the first and second diode stacks are independently addressable by applying different voltages to the first, second, and third terminals.

2. The LED light source of claim 1, wherein the dielectric layer and the first terminal form a reflective coating and the dielectric layer and the third terminal form a reflective coating.

3. The LED light source of claim 1, wherein the second terminal is adjacent to the first terminal, the second terminal and first terminal separated by only a dielectric layer.

4. The LED light source of claim 1, comprising a transparent conducting oxide in contact with the P doped layer of the second diode stack, the transparent conducting oxide in electrical contact with the third terminal through a via.

5. The LED light source of claim 1, wherein only the second diode stack is activated to emit light.

6. The LED light source of claim 5, wherein a light output of the LED light source is controlled by pulse width modulation (PWM) of the current delivered to the third terminal.

7. The LED light source of claim 1, wherein only the first diode stack is activated to emit light.

8. The LED light source of claim 1, wherein both the first and the second diode stacks are activated to emit light.

9. The LED light source of claim 1, comprising a metal layer comprising a fourth metal, the metal layer coating sidewalls of the LED light source and in contact with the first and third terminals.

10. The LED light source of claim 1, wherein the LED light source is micro-LED light source.

11. The LED light source of claim 1, wherein a surface of the N-doped semiconductor layer of the first diode stack is a principal light emission surface of the LED light source and wherein the surface is roughened.

12. The LED light source of claim 1, comprising:
a third diode stack comprising: an N-doped semiconductor layer, a P-doped semiconductor layer, and an active region between the N and P doped layers configured to emit light, the third diode stack situated between the first and second diode stacks, the third diode stack separated from the first and second diode stacks by tunnel junctions; and
a fourth terminal comprising a fifth metal, the fourth terminal in contact with the N doped layer of the third diode stack.

13. The LED light source of claim 1, wherein the light emitted by the active region of the first diode stack has a different wavelength from the light emitted by the active region of the second diode stack.

14. The LED light source of claim 1, wherein the dielectric layer comprises a distributed Bragg reflector (DBR).

15. A LED light source comprising:
a first diode stack comprising: an N-doped semiconductor layer having a lateral electrical resistance, a P-doped semiconductor layer, and an active region between the N and P doped layers configured to emit light;
a second diode stack comprising: an N-doped semiconductor layer having a lateral electrical resistance greater than the lateral electrical resistance of the N-doped semiconductor layer of the first diode stack, a P-doped semiconductor layer, and an active region between the N and P doped layers configured to emit light;
a tunnel junction separating the first and second diode stacks;
a first terminal in contact with the N-doped layer of the first diode stack and with the N-doped layer of the second diode stack; and
a second terminal in contact with the P-doped layer of the second diode stack.

16. The LED light source of claim 15, wherein the active region of the first diode stack may be either activated to emit light or deactivated depending on the voltages applied to the first and the second terminals.

17. The LED light source of claim 15, wherein the active region of the first diode stack and the active region of the second diode stack are activated to emit light, a light output of the LED light source having a super-linear increase in light output power with respect to voltage as the voltage applied to the second terminal exceeds 5.5 volts.

18. The LED light source of claim 15, wherein the active region of the first diode stack is deactivated while the active region of the second diode stack is activated to emit light.

19. The LED light source of claim 15, wherein a surface of the N-doped semiconductor layer of the first diode stack is a principal light emission surface of the LED light source.

20. The LED light source of claim 15, wherein the second terminal comprises a transparent conducting oxide and the second terminal is a principal light emission surface of the LED light source.
